(19) United States
(12) Patent Application Publication
(10) Pub. No.: US 2024/0381619 A1
(43) Pub. Date: Nov. 14, 2024

(54) SEMICONDUCTOR INTEGRATED CIRCUIT DEVICE AND METHOD OF MANUFACTURING THE SAME

(71) Applicant: SK hynix Inc., Gyeonggi-do (KR)

(72) Inventor: Jun Sik KIM, Gyeonggi-do (KR)

(21) Appl. No.: 18/656,609

(22) Filed: May 7, 2024

(30) Foreign Application Priority Data
May 12, 2023 (KR) 10-2023-0061894
Feb. 5, 2024 (KR) 10-2024-0017615

(51) Int. Cl. H10B 12/00; H01L 29/78

(52) U.S. Cl. CPC H10B 12/315; H01L 29/7827

(57) ABSTRACT

A semiconductor integrated circuit device may include a target fine pattern and an adjacent fine pattern. The target fine pattern may have a first width, a first length and a first height. The first width may be gradually decreased toward a lower region. The first length may be gradually increased toward the lower region. The first height may be greater than the first width and the first length. The adjacent fine pattern may have contact with the target fine pattern along a lengthwise direction. The adjacent fine pattern may have a second width, a second length and the first height. The second width may be gradually decreased toward the lower region. The second length may be gradually decreased toward the lower region.

### CROSS-REFERENCE TO RELATED APPLICATION

The present application claims priority under 35 U.S.C. § 119 (a) to Korean patent application number 10-2023-0061894, filed on May 12, 2023, and Korean patent application number 10-2024-0017615, filed on Feb. 5, 2024, which are incorporated herein by reference in their entirety.

### BACKGROUND

### 1. Technical Field

Various embodiments of the present disclosure generally relate to a semiconductor integrated circuit device and a method of manufacturing the same, more particularly, to a semiconductor integrated circuit device including a fine pattern having a high aspect ratio and a method of manufacturing the semiconductor integrated circuit device.

### 2. Related Art

In order to satisfy a good performance and a low cost required by customers, it may be required to increase an integration density of a semiconductor device.

In order to improve the integration density, a vertical transistor technology and a stack type memory device may be proposed. In the vertical transistor technology, a channel of a transistor may be vertically formed on a substrate. In the stack type memory device, a plurality of memory cells may be stacked.

The vertical transistor technology and the stack type memory device may include a fine pattern having a high aspect ratio. The high aspect ratio may have a height or a thickness relatively greater than a small area (width×length).

When the fine pattern or a fine contact hole having the high aspect ratio is formed, an amount of an etching gas may be gradually decreased in a lower region thereof. Thus, a width of the fine pattern or the fine contact hole with respect to the height may be changed. Particularly, when the fine pattern is a conductive layer or an active pillar in which a channel is formed, electrical characteristics of a device may be changed.

### SUMMARY

According to an embodiment of the present disclosure, there may be provided a semiconductor integrated circuit device. The semiconductor integrated circuit device may include a target fine pattern and an adjacent fine pattern. The target fine pattern may have a first width, a first length and a first height. The first width may be gradually decreased toward a lower region. The first length may be gradually increased toward the lower region. The first height may be greater than a maximum value of the first width and a maximum value of the first length. The adjacent fine pattern may have contact with the target fine pattern along a lengthwise direction. The adjacent fine pattern may have a second width, a second length and the first height. The second width may be gradually decreased toward the lower region. The second length may be gradually decreased toward the lower region.

In an embodiment, a difference between the first length of the lower region and a first length of a lower region of the target fine pattern may be substantially identical to a difference between a second length of the upper region of the adjacent fine pattern and the second length of the lower region of the adjacent fine pattern.

In an embodiment, the first width may be substantially identical to the second width.

According to an embodiment of the present disclosure, there may be provided a method of manufacturing a semiconductor integrated circuit device. In the method of manufacturing the semiconductor integrated circuit device, a recess may be formed at a first structure having a first height. The recess may have a first width less than the first height. The recess may extend in a lengthwise direction substantially perpendicular to a direction corresponding to the first width. The recess may be filled with a target material to form a target line. At least one adjacent fine pattern may be formed in the target line to form target fine patterns at both sides of the adjacent fine pattern.

In an embodiment, the recess, the target line, the adjacent fine pattern and the target fine patterns may have the first width gradually decreased toward a lower region thereof.

In an embodiment, forming the adjacent fine pattern may include etching the target line to form a trench having a length gradually decreased toward the lower region, filling the trench to form a layer different from the target material, and planarizing the layer to form the adjacent fine pattern.

According to an embodiment of the present disclosure, there may be provided a semiconductor integrated circuit device. The semiconductor integrated circuit device may include a pair of word line structures, at least one active pillar and at least one device isolation pattern.

In an embodiment, the pair of word line structures may be divided by recesses. The recesses may have a first height. The recesses may extend parallel to each other along a first direction. The active pillar and the device isolation pattern may be alternately arranged in the recess between the pair of word line structures. The active pillar may have a first width, a first length and a first height. The first width may be gradually decreased toward a lower region. The first length may be gradually increased toward the lower region. The device isolation pattern may have a second width, a second length and the first height. The second width may be gradually decreased toward the lower region. The second length may be gradually decreased toward the lower region.

In an embodiment, the first width and the second width may be parallel to a second direction substantially perpendicular to the first direction. The first width may be substantially identical to the second width. The first length and the second length may be substantially parallel to the first direction.

According to an embodiment of the present disclosure, there may be provided a method of manufacturing a semiconductor integrated circuit device. In the method of manufacturing the semiconductor integrated circuit device, a base layer may be prepared. The base layer may include a plurality of bit lines. The bit lines may be electrically isolated from each other. The bit lines may extend parallel to each other. A first conductive structure may be formed on the base layer. The first conductive structure may have a first height. The conductive structure may be etched to form at least one recess, thereby separating the conductive structure into a plurality of word line structures. The recess may have a first width gradually decreased toward a lower region. The recess may extend in a first direction substantially perpendicular to an extending direction of the bit lines. A gate dielectric layer may be formed on a sidewall of each of the word line structures. An active line may be formed in the recess. A plurality of device isolation patterns may be formed at the active line to form a plurality of self-organized active pillars. The device isolation patterns may have a second width and a second length. The second width may be gradually decreased toward the lower region. A drain may be formed in a lower region of each of the active pillars. A source may be formed in an upper region of each of the active pillars.

In an embodiment, forming the device isolation pattern may include etching the active line to form a trench having the second width and the second length, forming an insulation layer on the base layer, the word line structures and the active line to fill the trench, and planarizing the insulation layer until an upper surface of the active line is exposed to form the device isolation pattern.

According to an embodiment of the present disclosure, the target fine pattern such as the active pillar, which may be used as a channel of a vertical transistor, may be formed by forming the adjacent fine pattern such as the device isolation pattern in the self-organization way. That is, by forming the adjacent fine pattern with the width and the length gradually decreased toward the lower region, the length of the target fine pattern may be compensated to secure an area of a bottom surface and a total volume of the target fine pattern.

Therefore, the channel region of the transistor or the pattern having the high aspect ratio may have improved electrical characteristics.

Further, the compensation of the area and the volume of the active pillar used for the target fine pattern may be performed without an additional mask and an additional etching process to reduce a fabrication cost and a fabrication time.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIGS. 1 and 2 are perspective views illustrating a target fine pattern and an adjacent fine pattern of a semiconductor integrated circuit device in accordance with an embodiment of the present disclosure;

FIG. 3 is a perspective view illustrating a target fine pattern in accordance with an embodiment of the present disclosure;

FIGS. 4A to 4D are perspective views illustrating a method of manufacturing a semiconductor integrated circuit device with a target fine pattern and an adjacent fine pattern in accordance with an embodiment of the present disclosure;

FIG. 5 is a perspective view illustrating a semiconductor integrated circuit device with an active pillar in accordance with an embodiment of the present disclosure;

FIGS. 6A to 12A are plan views illustrating a method of manufacturing a semiconductor integrated circuit device in accordance with an embodiment of the present disclosure;

FIGS. 6B to 12B are cross-sectional views taken along a line b-b′ in FIGS. 6A to 12A, respectively;

FIGS. 11C and 12C are cross-sectional views taken along a line c-c′ in FIGS. 11A and 12A, respectively;

FIGS. 11D and 12D are cross-sectional views taken along a line d-d′ in FIGS. 11A and 12A, respectively; and

FIGS. 13A to 13C are cross-sectional views illustrating a method of manufacturing a device isolation pattern in accordance with an embodiment of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the embodiments of the present disclosure as defined in the appended claims.

The present invention is described herein with reference to cross-section and/or plan illustrations of embodiments of the present disclosure. However, the embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

In embodiments of the present disclosure, a fine pattern (hereinafter referred to as a target fine pattern) may be emergently formed by a self-organization. That is, the self-organization may form the target fine pattern as a byproduct of a patterning process for forming an adjacent fine pattern without a direct patterning process for forming the target fine pattern.

Further, a high aspect ratio may be about a minimum 30:1 of a horizontal length (or a width) with respect to a vertical length. That is, a height or a thickness, for example, a z-axial length of a pattern, a hole, a recess or a space may be about 30 times a width, for example, an x-axial maximum length and a length, for example, a y-axial maximum length. The 30:1 may be one example of the high aspect ratio, and the embodiments are not limited thereto.

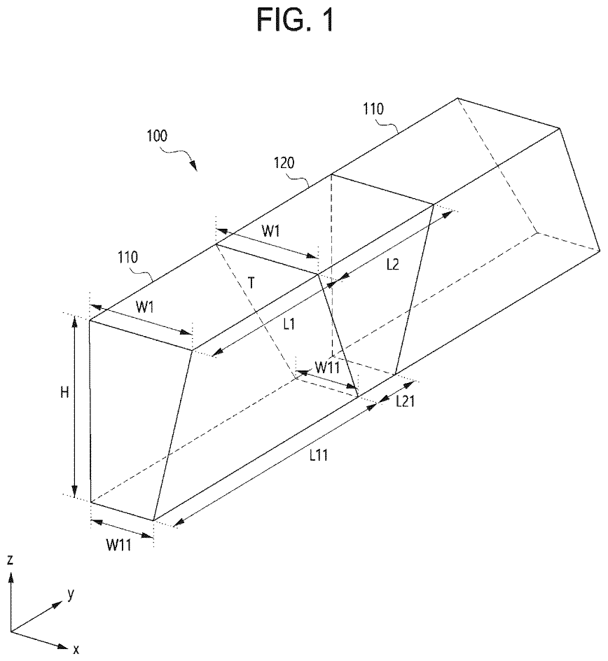

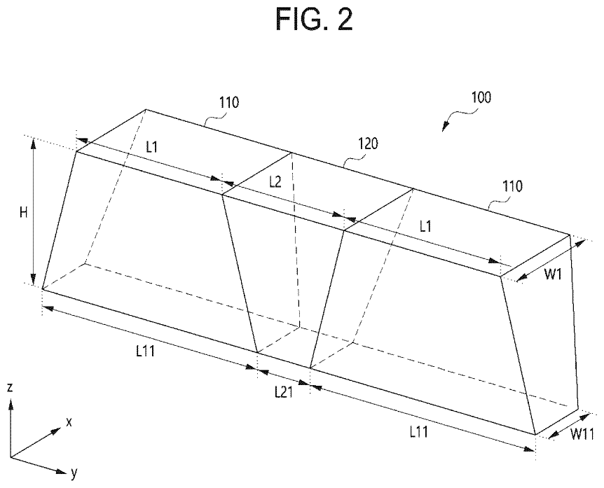

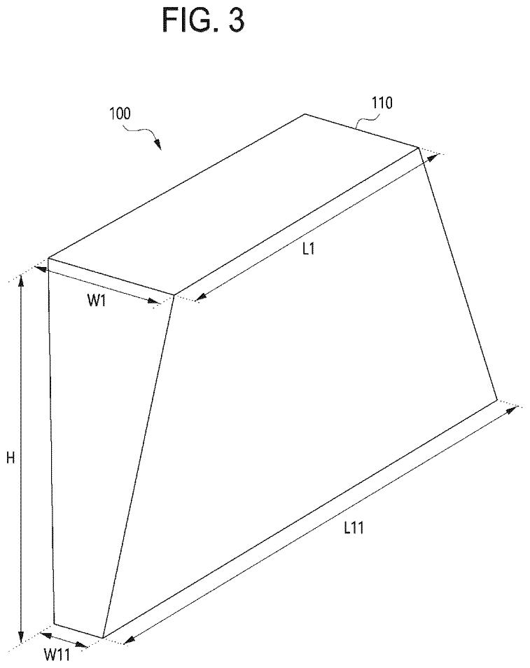

FIGS. 1 and 2 are perspective views illustrating a target fine pattern and an adjacent fine pattern of a semiconductor integrated circuit device in accordance with an embodiment of the present disclosure, and FIG. 3 is a perspective view illustrating a target fine pattern in accordance with an embodiment of the present disclosure.

Referring to FIGS. 1 to 3, a semiconductor integrated circuit device 100 of an embodiment may include target fine patterns 110 and at least one adjacent fine pattern 120.

The target fine patterns 110 may have a first width W1 and W11, a first length L1 and L11 and a first height H or a first thickness. The first width W1 and W11 may correspond to an x-axial direction. The first length L1 and L11 may correspond to a y-axial direction. The first height H may correspond to a z-axial direction.

The adjacent fine pattern 120 may be positioned between the target fine patterns 110. The adjacent fine pattern 120 may have the first width W1 and W11, a second length L2 and L21 and the first height H. That is, the first width W1 and W11 of the adjacent fine pattern 120 may be substantially the same as the first width W1 and W11 of the target fine pattern 110. The target fine pattern 110 and the adjacent fine pattern 120 may be alternately arranged side by side along the y-axial direction to form one line.

In an embodiment, the first width W1 may indicate a width of an upper region in the target fine pattern 110 and the adjacent fine pattern 120. The first width W11 may indicate a width of a lower region in the target fine pattern 110 and the adjacent fine pattern 120. The first length L1 may indicate a length of the upper region in the target fine pattern 110. The first length L11 may indicate a length of the lower region in the target fine pattern 110. The second length L2 may indicate a length of the upper region in the adjacent fine pattern 120. The second length L21 may indicate a length of the lower region in the adjacent fine pattern 120.

In an embodiment, the at least one adjacent fine pattern 120 may be inserted into a target line including the successively arranged target fine patterns 110 so that the target line may be divided into the target fine patterns 110 by the adjacent fine pattern 120.

When the first width W1 and W11, the first length L1 and L11 and the second length L2 and L21 are remarkably less than the first height H, the target fine patterns 110 and the adjacent fine pattern 120 may have a high aspect ratio. The remarkable less may mean that a difference of no less than about 30 times in a range of the high aspect ratio.

As is well known, when at least one etching process is performed to form a pattern with the high aspect ratio, a sufficient amount of an etching gas may not be applied in a downward (−z) direction. Thus, a volume of the pattern with the high aspect ratio may be gradually decreased toward a lower region.

In contrast, the target fine patterns 110 may be self-organized by the adjacent fine pattern 120. Thus, a volume of the target fine pattern 110, i.e., a size of the target fine pattern 110 may be determined to be dependent upon a size of the adjacent fine pattern 120.

In an embodiment, as the second length L2 of the adjacent fine pattern 120 may be gradually decreased toward the lower region, the first length L1 of the target fine pattern 110 may be gradually increased toward the lower region. That is, the second length L2 and L21 of the adjacent fine pattern 120 and the first length L1 and L11 of the target fine pattern 110 may have a complementary relation.

As a result, the target fine pattern 110 may have the gradually decreased width toward the lower region. In contrast, the target fine pattern 110 may have the gradually increased length toward the lower region. Thus, the size of the target fine pattern 110, i.e., the volume of the target fine pattern 110 may be maintained within an initial set value to secure a contact resistance characteristic and other electrical characteristic.

In an embodiment, the target fine pattern 110 may include a vertical active pillar of a switching device. The adjacent fine pattern 120 may include a device isolation pattern, but the embodiments are not limited thereto. For example, the target fine pattern 110 may include at least one of a semiconductor pattern such as the active pillar and a conductive pattern such as a metal plug. The adjacent fine pattern 120 may include an insulation pattern.

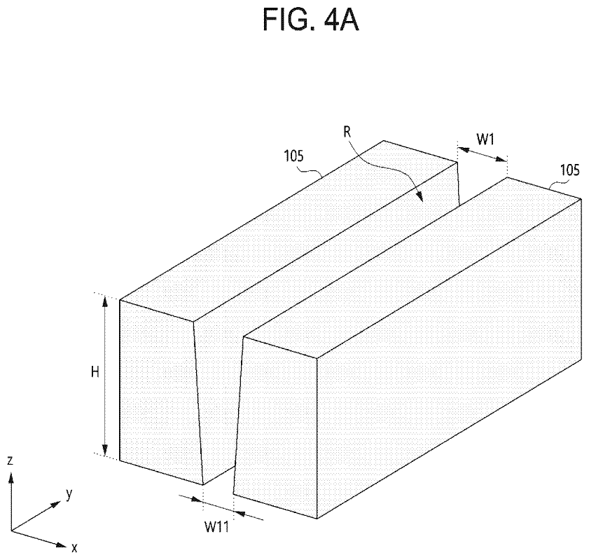

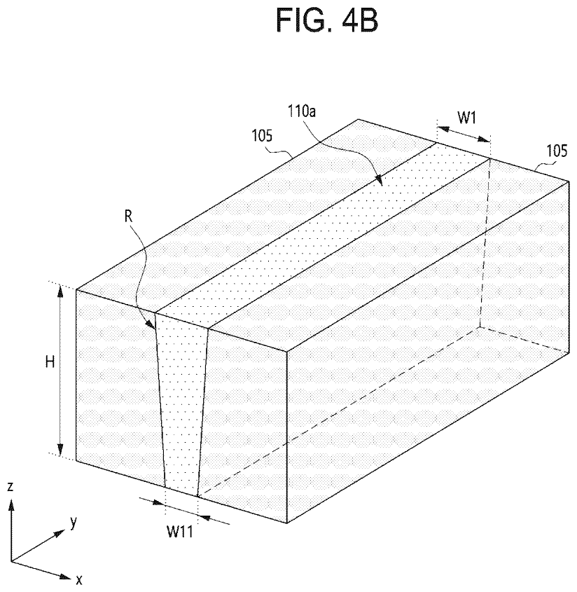

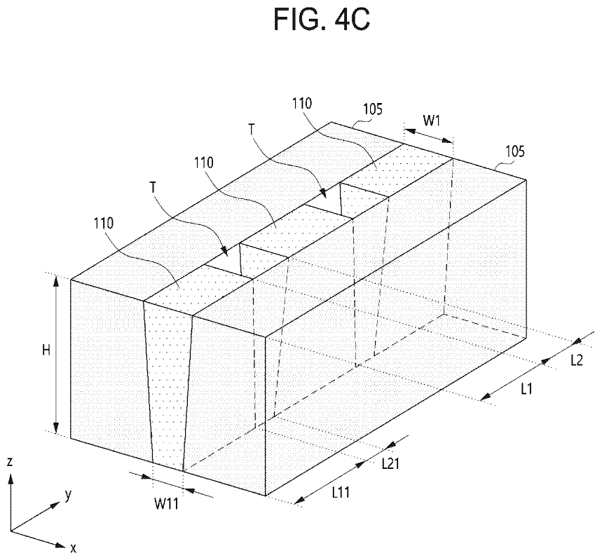

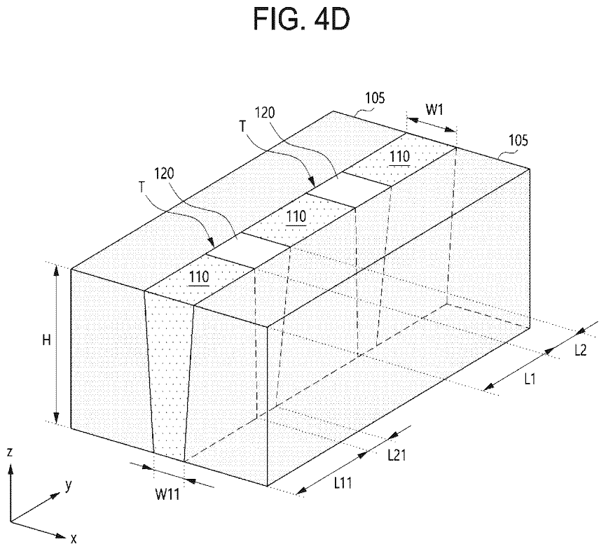

FIGS. 4A to 4D are perspective views illustrating a method of manufacturing a semiconductor integrated circuit device with a target fine pattern and an adjacent fine pattern in accordance with an embodiment of the present disclosure.

Referring to FIG. 4A, a first structure may be formed on a base layer. The first structure may have a first height H or a first thickness. For example, the first structure may include at least one layer. The at least one layer may include an insulation layer or a conductive layer.

A recess R may be formed in the first structure to divide the first structure into a pair of first lines 105. The recess R may be formed by etching the first structure using an etchant, for example, an etching gas.

In an embodiment, the recess R may have a linear hole structure extending in the y-direction. The linear hole structure may have a first width W1. The first width W1 of the recess R may be remarkably less than the first height H so that the recess R may have a high aspect ratio. Thus, in the etching process for forming the recess R, a supplied amount of the etching gas may be gradually decreased toward a lower region in the recess R so that the first width W1 of the recess R may be gradually decreased toward the lower region. A reference numeral W11 may indicate a width of the lower region in the recess R.

Referring to FIG. 4B, a first layer may be formed on the first line 105 to fill up the recess R with the first layer. The first layer may have an etching selectivity with respect to the first line 105. The first layer may be planarized until an upper surface of the first line 105 is exposed to form a target line 110a in the recess R. Because the target line 110a may be formed in the recess R, the target line 110a may have a shape substantially the same as a shape of the recess R. Thus, the target line 110a may have the first width W1 and W11 gradually decreased toward the lower region. The target line 110a may extend in the y-direction.

Referring to FIG. 4C, at least one trench T may be formed in the target line 110a. The target line 110a may be divided into target fine patterns 110 by the trench T. That is, the target fine patterns 110 may be defined in a self-organization by forming the trench T.

As mentioned above, the trench T may be formed by etching the target line 110a. The target line 110a may be supported by portions of the first line 105 at both sides of the target line 110a. Thus, the target line 110a and the trench T in the target line 110a may have the same first width W1 and W11 and the same first height H.

In an embodiment, the trench T may have the limited second length L2 along the y-axial direction. Further, the second length L2 of the trench T may be greatly less than the first height H. Thus, the trench T may also have a high aspect ratio.

Therefore, in the etching process for forming the trench T, an upper region in the trench T may be etched more than a lower region in the trench T. As mentioned above, because the first width W1 and W11 of the trench T may be fixed by the first line 105, the second length L2 of the trench T may be gradually decreased toward the lower region in the etching process for forming the trench T. A reference numeral L21 may indicate a length of the lower region in the trench T. Thus, the trench T may have the first width W1 and W11 and the second length L2 and L21 gradually decreased toward the lower region.

As a result, the target fine pattern, which may be formed in the self-organization by the trench T, may have the compensated length L11 of the lower region corresponding to a decreased length of the trench T.

Referring to FIG. 4D, a second layer may be formed on the first line 105 and the target fine pattern 110 to fill up the trench T with the second layer. For example, the second layer may have an etching selectivity with respect to the first line 105 and the first layer. The second layer may be planarized until the first line 105 and the target fine pattern 110 are exposed to form an adjacent fine pattern 120 in the trench T. Because the adjacent fine pattern 120 may be formed in the trench T, the adjacent fine pattern 120 may have a shape substantially the same as the shape of the trench T.

According to embodiments of the present disclosure, the target fine pattern 110 may be formed in the self-organization by the adjacent fine pattern 120. Thus, changes of a contact area and a volume of the target fine pattern 110 may be reduced.

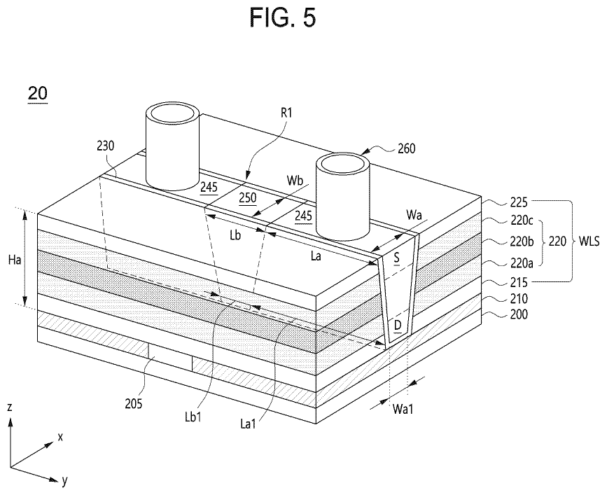

FIG. 5 is a perspective view illustrating a semiconductor integrated circuit device with an active pillar in accordance with an embodiment of the present disclosure.

Referring to FIG. 5, a semiconductor integrated circuit device 20 of an embodiment of the present disclosure may include a base layer 200, a bit line 210, a pair of word line structures WLS, an active pillar 245, a gate dielectric layer 230, a device isolation pattern 250 and a capacitor electrode 260.

In an embodiment, the base layer 200 may include a semiconductor layer, a glass layer, etc. The semiconductor layer may include a silicon layer, an epitaxial layer, a silicon germanium layer, etc. The base layer 200 may include a semiconductor substrate, a glass substrate, etc.

The bit line 210 may include at least one line extending in a y-axial direction. The bit line 210 may be formed in the base layer 200. Alternatively, the bit line 210 may include a linear pattern on the base layer 200. When the bit line 210 includes a plurality of lines, the bit lines 210 may be electrically isolated from each other by a lower insulation layer 205. The bit lines 210 may include conductive layers such as a polysilicon layer, a titanium nitride layer, a tungsten layer, and a combination thereof.

The pair of word line structures WLS may parallelly extend in the y-axial direction. The word line structures WLS may be electrically isolated from each other by a recess R1. Although not depicted in drawings, the bit line 210 or an ohmic contact layer on the bit line 210 may be exposed through the recess R1. In an embodiment, the word line structures WLS may have a first height Ha or a first thickness. The word line structures WLS may include at least one conductive layer. For example, the word line structure WLS may include a first insulation interlayer 215, a word line conductive layer 220 and a second insulating interlayer 225. The word line conductive layer 220 may include a single conductive layer or a multi-layered conductive layer. The word line conductive layer 220 may correspond to a vertical gate of a three-dimensional (3D) vertical transistor. The word line conductive layer 220 may include at least one of silicon, a metal, metal nitride, metal silicide and a combination thereof. For example, the word line conductive layer 220 may include at least one of polysilicon, molybdenum nitride, molybdenum, titanium nitride, titanium, tungsten and a combination thereof. Alternatively, the word line conductive layer 220 may include a conductive material having a low work function of no more than about 4.5 eV, which may be a silicon mid-gap work function for reducing a threshold voltage of a transistor, to form a single type vertical gate. Further, the word line conductive layer 220 may include a first work function layer 220a, a second work function layer 220b and a third work function layer 220c sequentially stacked. For example, at least one of the first and third work function layers 220a and 220c may have a work function lower than a work function of the second work function layer 220b. The first and third work function layers 220a and 220c may include a polysilicon layer including conductive impurities, or a conductive material having a work function of no more than about 4.5 eV. The second work function layer 220b may include a metal higher than the silicon mid-gap work function. For example, the second work function layer 220b may include molybdenum, molybdenum nitride, a stack of molybdenum nitride and molybdenum, tungsten, titanium nitride, ruthenium, and a combination thereof. At least one of the first and second insulating interlayer 215 and 225 may include at least one of a silicon oxide layer, a silicon nitride layer, a silicon carbon nitride layer and a silicon oxynitride layer. Thus, a dual type vertical gate may be formed using the word line conductive layer 220 having the first to third work function layers 220a, 220b and 220c.

The active pillar 245 may include a plurality of pillars arranged between the word line structure WLS. The active pillars 245 may be formed at positions having contact with the bit line 210 to be operated as an active region of the transistor. The active pillar 245 may have the first height Ha, a first width Wa and Wa1 and a first length La and La1. The first height Ha of the active pillar 245 may be substantially the same as the first height Ha of the word line structure WLS. The first width Wa and Wa1 may correspond to an extending length of the active pillar 245 in the x-axial direction. The first length La and La1 may correspond to an extending length of the active pillar 245 in the y-axial direction. Because the first width Wa and Wa1 and the first length La and La1 may be remarkably less than the first height Ha, the active pillar 245 may have a high aspect ratio. Thus, the first width Wa1 of a lower region in the active pillar 245 may be narrower than the first width Wa of an upper region in the active pillar 245. That is, the active pillar 245 may have a gradually decreased width toward the lower region. The first length La1 of the lower region in the active pillar 245 may be longer than the first length La of the upper region in the active pillar 245. That is, the active pillar 245 may have a gradually increased length toward the lower region. The active pillar 245 may include a semiconductor material having an etching selectivity with respect to the second insulating interlayer 225 of the word line structure WLS. The active pillar 245 may form a channel. For example, the semiconductor material may include at least one of single crystalline silicon, polysilicon, germanium, silicon germanium and IGZO. In an embodiment, the semiconductor material may include a polysilicon layer with p type impurities.

A drain D may be formed in the lower region of the active pillar 245. A source S may be formed in the upper region of the active pillar 245. Although not depicted in drawings, an ohmic contact layer may be interposed between the drain D and the source S. Further, the drain D may be positioned adjacent to the first work function layer 220a. The source S may be positioned adjacent to the third work function layer 220c.

The gate dielectric layer 230 may be interposed between the word line structure WLS and the active pillar 245. The gate dielectric layer 230 may include silicon oxide, silicon nitride, a high dielectric material, and a combination thereof. Particularly, the gate dielectric layer 230 may include silicon oxide, silicon nitride, metal oxide, metal oxynitride, metal silicate, a high-k material, a ferroelectric material, an anti-ferroelectric material, and a combination thereof.

The device isolation pattern 250 may be formed between the active pillars 245 among spaces between the word line structures WLS. The device isolation pattern 250 may have the first height Ha, a second width Wb and a second length Lb and Lb1. In an embodiment, a second width and the second length Lb1 of a lower region in the device isolation pattern 250 may be less than the second width Wb and the second length Lb of an upper region in the device isolation pattern 250, respectively. That is, the width and the length of the device isolation pattern 250 may be gradually decreased toward the lower region. The device isolation pattern 250 may include an insulation material for electrically isolating the active pillar 245. The second widths Wb of the device isolation pattern 250 may be substantially the same as the first width Wa and Wa1 of the active pillar 245.

For example, when the semiconductor integrated circuit device 20 includes a DRAM, the semiconductor integrated circuit device 20 may further include the capacitor electrode 260. The capacitor electrode 260 may be formed on the active pillar 245. The capacitor electrode 260 may correspond to a storage node of data storage. The capacitor electrode 260 may be electrically connected with the source S of the active pillar 245. The capacitor electrode 260 may have a cylindrical shape, but the embodiments are not limited thereto. The capacitor electrode 260 may include a metal, a noble metal, metal nitride, conductive metal oxide, conductive noble metal oxide, metal carbon, metal silicide, and a combination thereof. Although not depicted in drawings, a dielectric layer and a plate electrode may be formed on the capacitor electrode 260 to form the data storage.

According to embodiments of the present disclosure, the active pillar 245 may have the aspect ratio. However, the length La1 of the lower region may be longer than the length La of the upper region. Thus, the active pillar 245 may have the width Wa→Wa1 gradually decreased toward the lower region and the length La→La1 gradually increased toward the lower region to maintain the contact area and the total volume. Thus, the contact area between the drain D and the bit line and the volume of the active pillar 245 may be increased to reduce characteristic changes of the transistor caused by applying a gate voltage. As a result, the electrical characteristics of the vertical transistor may be secured.

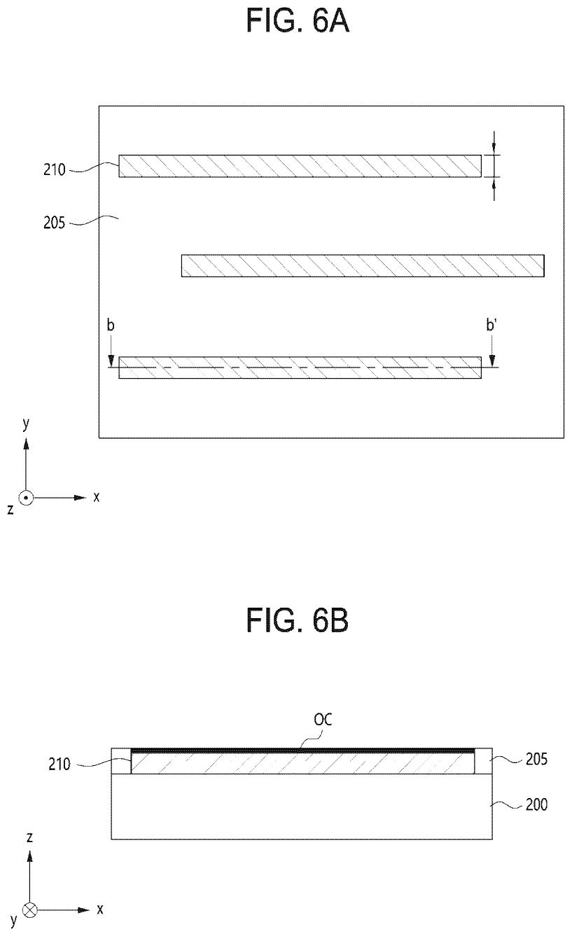

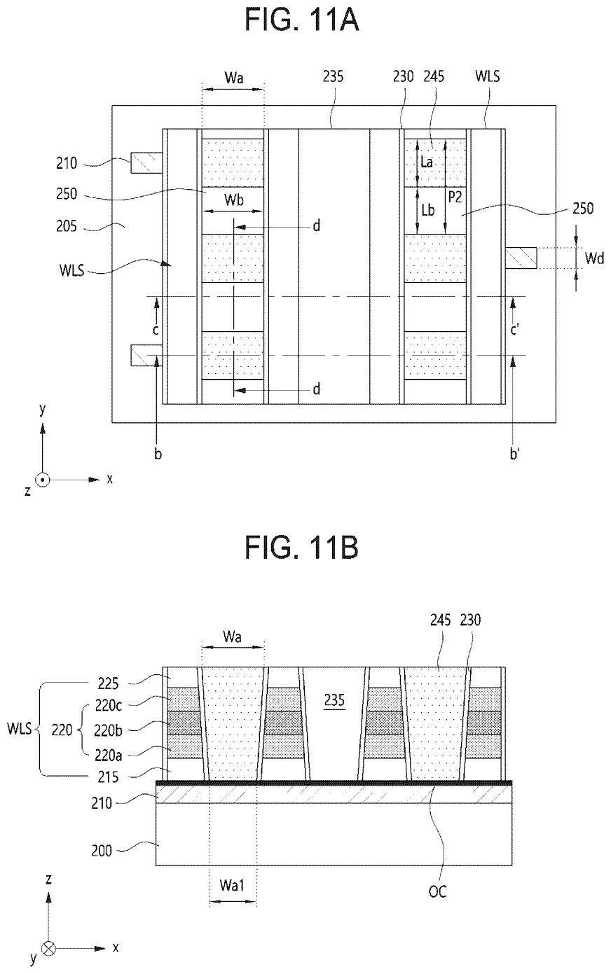

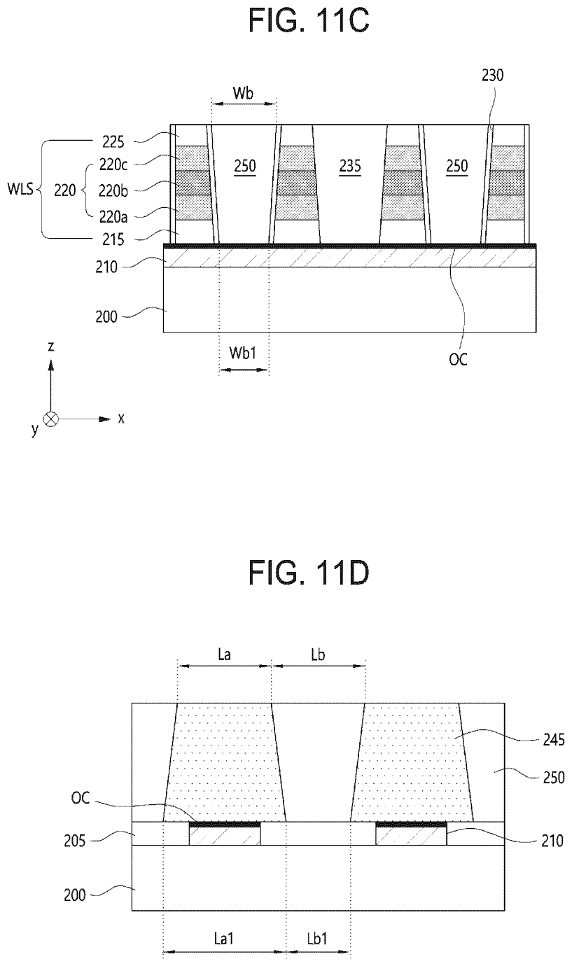

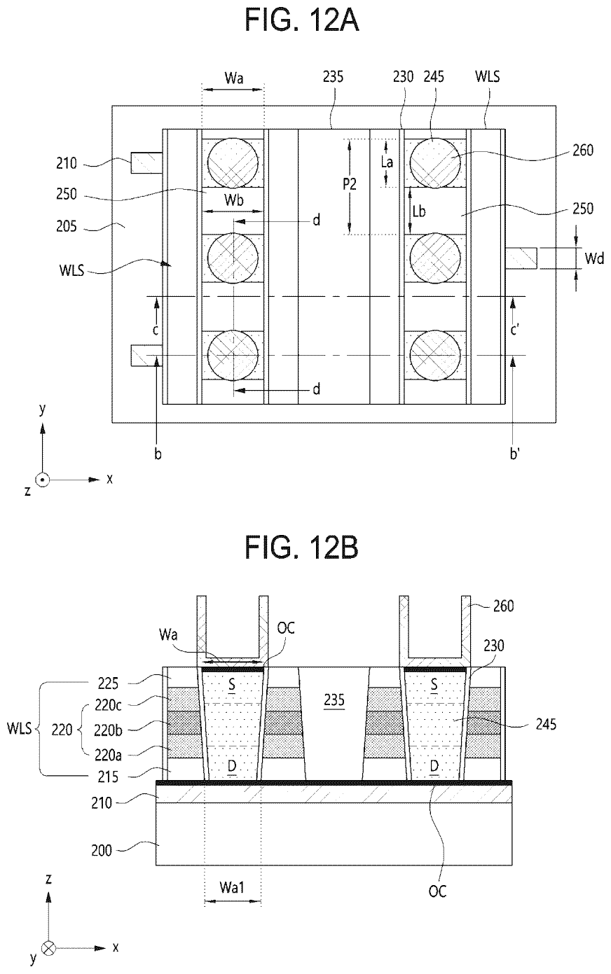

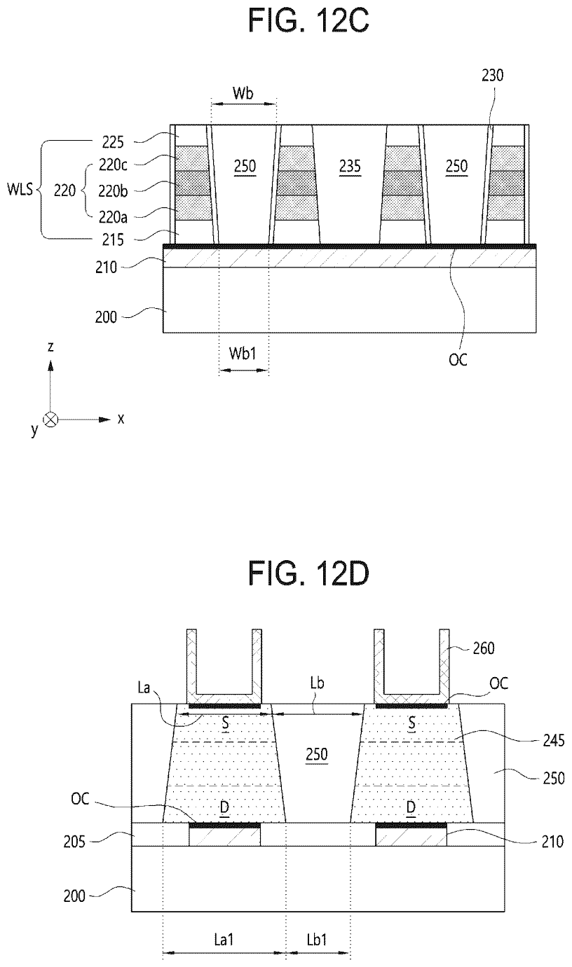

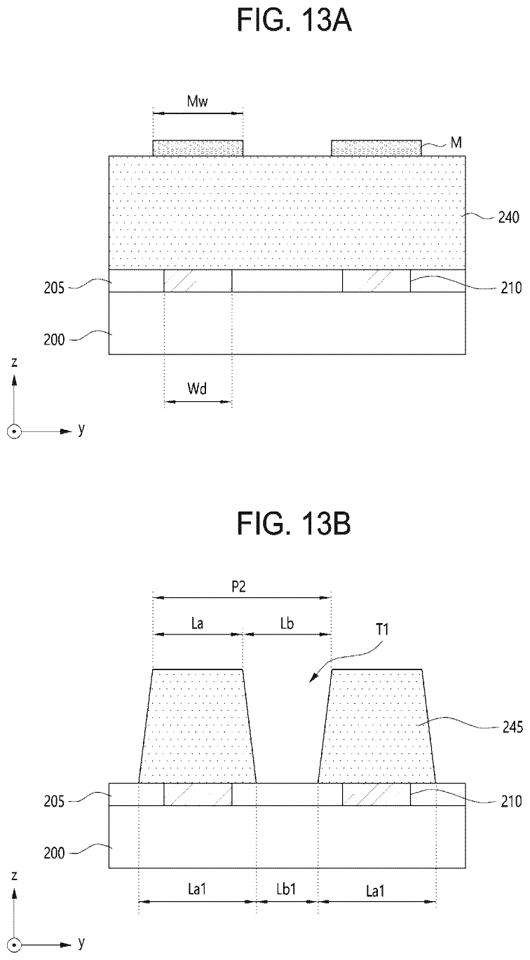

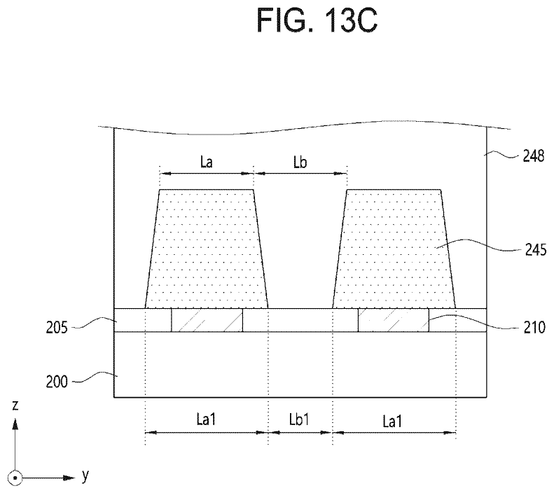

FIGS. 6A to 12A are plan views illustrating a method of manufacturing a semiconductor integrated circuit device in accordance with an embodiment of the present disclosure. Specifically, FIGS. 6B, 7B, 8B, 9B, 10B, 11B, and 12B are cross-sectional views taken along a line b-b′ in FIGS. 6A, 7A, 8A, 9A, 10A, 11A, and 12A, respectively; FIGS. 11C and 12C are cross-sectional views taken along a line c-c′ in FIGS. 11A and 12A, respectively; FIGS. 11D and 12D are cross-sectional views taken along a line d-d′ in FIGS. 11A and 12A, respectively; and FIGS. 13A to 13C are cross-sectional views illustrating a method of manufacturing a device isolation pattern in accordance with an embodiment of the present disclosure.

Referring to FIGS. 6A and 6B, a plurality of bit lines 210 may be formed at a base layer 200. In an embodiment, the bit lines 210 may be formed in the base layer 200. Alternatively, the bit lines 210 may be a linear pattern on the base layer 200.

For example, a lower insulation layer 205 may be formed on the base layer 200. The lower insulation layer 205 may include at least one insulation layer. The lower insulation layer 205 may be patterned to form a bit line hole. A conductive layer may be formed on the lower insulation layer 205 to fill up the bit line hole with the conductive layer. The conductive layer may be planarized until the lower insulation layer 205 is exposed to form the bit lines 210 in the bit line hole. The bit lines 210 may extend parallel to each other along the x-axial direction. The bit lines 210 may be electrically isolated from each other by the lower insulation layer 205.

The bit lines 210 may include a metal layer, a polysilicon layer, a titanium nitride layer, a tungsten layer, and a combination thereof. For example, an ohmic contact layer OC may be formed on the bit lines 210. The ohmic contact layer OC may be formed by a metal silicide formation process.

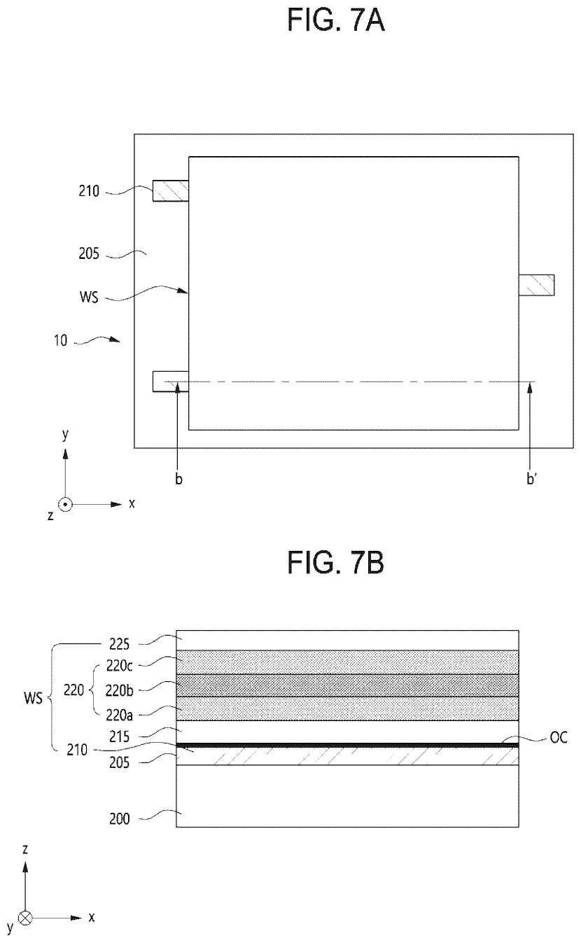

Referring to FIGS. 7A and 7B, a conductive structure WS may be formed on the base layer 200 with the bit lines 210. In an embodiment, a first insulating interlayer 215 may be formed on the base layer 200 with the bit lines 210. A word line conductive layer 220 may be formed on the first insulating interlayer 215. The first insulating interlayer 215 may electrically isolate the word line conductive layer 220 from the bit line 210. The word line conductive layer 220 may be formed by sequentially forming a first work function layer 220a, a second work function layer 220b and a third work function layer 220c on the first insulating interlayer 215. As mentioned above, the first work function layer 220a, which may be positioned in the lower region of the word line conductive layer 220, and the third work function layer 220c, which may be positioned in the upper region of the word line conductive layer 220, may have the work functions lower than the work function of the second work function layer 220b. Thus, a characteristic deterioration and a threshold voltage caused by a single channel effect of a transistor may be compensated. A second insulating interlayer 225 may be formed on the word line conductive layer 220. For example, the first and second insulating interlayers 215 and 225 may include a silicon oxide layer, but the embodiments are not limited thereto. Further, the first to third work function layers 220a, 220b and 220c may be formed by a thin layer deposition process capable of readily controlling a thickness. Thus, the first to third work function layers 220a, 220b and 220c may have proper thicknesses in accordance with positions of a source and a drain.

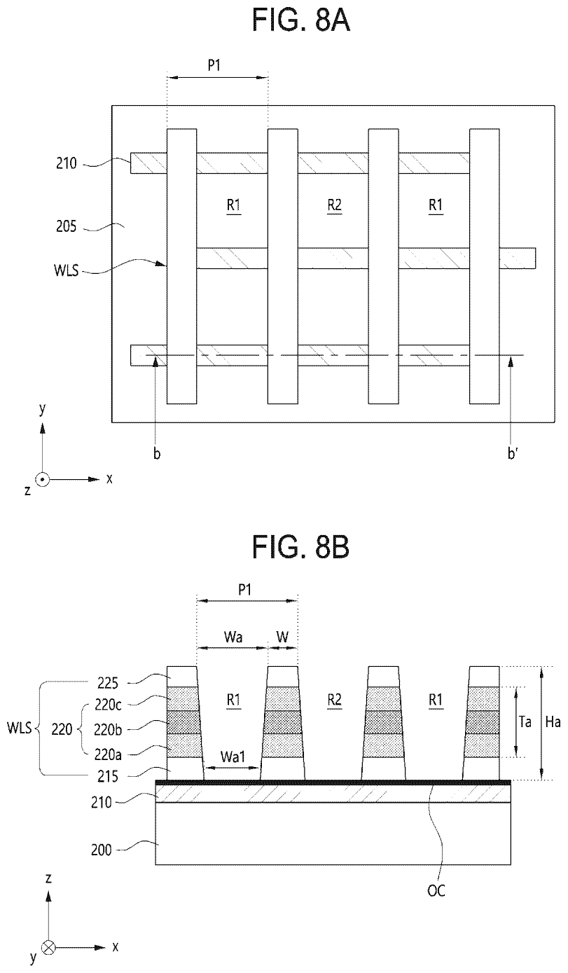

Referring to FIGS. 8A and 8B, the conductive structure WS may be patterned to form a plurality of word line structures WLS.

For example, the second insulating interlayer 225, the word line conductive layer 220 and the first insulating interlayer 215 may be etched to form recesses R1 and R2. That is, the recesses R1 and R2 may be formed in the conductive structure WS to define the word line structures WLS. The word line structures WLS may parallelly extend in a direction intersected with the bit lines 210, for example, the y-axial direction.

As mentioned above, the word line structures WLS may be defined by the recesses R1 and R2. The word line structure WLS may have a width W, a length L and a height (thickness) Ha in accordance with characteristics and integration density of a device. As a result, a shape of the word line structure WLS may be determined dependently upon shapes of the recesses R1 and R2.

Recently, it may be required to provide the word line structure WLS with a pitch P1 approximated to a resolution of an exposing apparatus and a uniform thickness Ta for providing a low resistance. The pitch may be a sum of the width W of the word line structure WLS and the width Wa of the recess R1 or R2. Because the width W of the word line structure WLS and the width Wa and Wa1 of the recess R1 or R2 may be remarkably less than the thickness Ha of the word line structure WLS, the recesses R1 and R2 for defining the word line structure WLS may have the high aspect ratio.

Therefore, in etching the conductive structure WS to form the recesses R1 and R2, etching gases may not be smoothly supplied to the base layer 200 so that the recesses R1 and R2 may have the width gradually decreased toward the lower region. The reference numeral Wa may indicate the first width of the upper region in the recesses R1 and R2. The reference numeral Wa1 may indicate the first width of the lower region in the recesses R1 and R2.

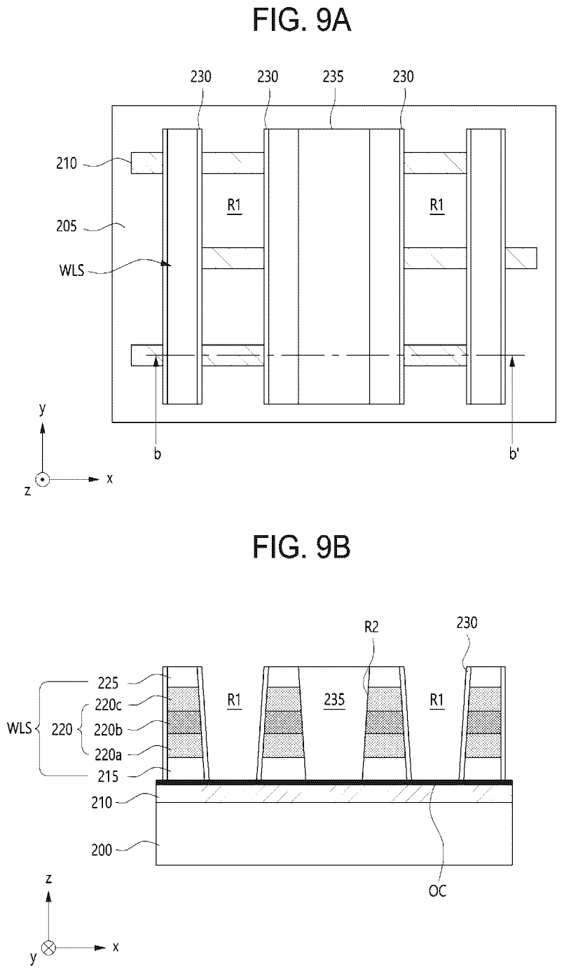

Referring to FIGS. 9A and 9B, a gate dielectric layer 230 may be formed on a sidewall of the word line structure WLS. The gate dielectric layer 230 may have a uniform thickness on the base layer 200 with the word line structure WLS. The gate dielectric layer 230 may be anisotropically etched to expose the bit lines 210. The gate dielectric layer 230 may be formed by an oxidation process, a deposition process, etc. For example, the gate dielectric layer 230 may be formed by an atomic layer deposition (ALD) process.

A part of the exposed bit lines 210 may be connected to the transistor. A remaining part of the exposed bit lines 210 may function as a signal line configured to transmit data. For example, when the exposed bit lines 210 through the recess R2 functions as the signal line, a blocking layer 235 configured to block the recess R2 may be selectively formed.

In an embodiment, the recess R1 configured to expose the bit lines 210 connected to the transistor may be blocked by various ways. An insulation layer may be formed on the base layer 200 to fill up the recess R2 with the insulation layer. The insulation layer may be planarized until the word line structure WLS is exposed to form the blocking layer 235. The blocked recess R1 may then be opened.

In an embodiment, the gate dielectric layer 230 may be formed before forming the blocking layer 235.

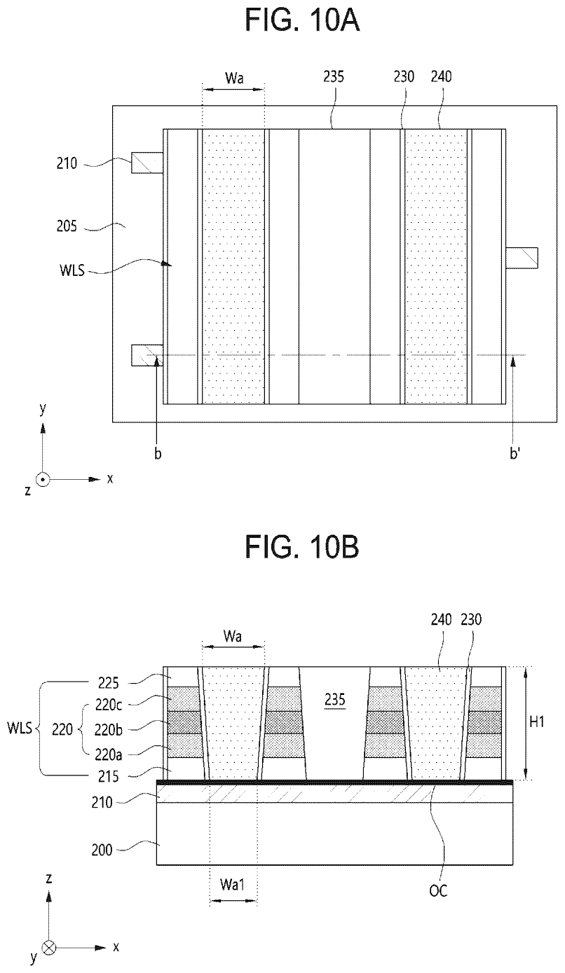

Referring to FIGS. 10A and 10B, an active line 240 may be formed in the recess R1 between the word line structures WLS. Particularly, an active layer may be formed on the base layer 200 to fill up the recess R1 with the active layer. The active layer may be used for forming the channel of the transistor. The active layer may include a single crystalline silicon layer, a polysilicon layer, a germanium layer, a silicon germanium layer, an indium gallium zinc oxide (IGZO) layer, etc. For example, the active layer may include the polysilicon layer with conductive impurities such as p type impurities. The active layer may be planarized until an upper surface of the word line structure WLS is exposed to form the active line 240 in the recess R1.

As mentioned above, because the active line 240 may be formed in the recess R1, the active line 240 may have a shape substantially the same as a shape of the recess R1. Further, the gate dielectric layer 230 may have a very thin thickness with respect to the width Wa and Wa1 of the recess R1. Thus, the active line 240 may have a width substantially the same as the width Wa and Wa1 of the recess R1.

Therefore, the active line 240 may have the first width Wa and Wa1 gradually decreased toward the lower region similarly to the recess R1. The active line 240 may extend in the y-axial direction. The active line 240 and the word line structure WLS may be electrically isolated from each other by the gate dielectric layer 230.

Referring to FIGS. 11A and 11B, a device isolation pattern 250 may be formed at the active line 240 to define active pillars 245 in the self-organization.

Hereinafter, a process for forming the device isolation pattern 250 may be illustrated with reference to FIGS. 13A to 13C.

Referring to FIG. 13A, a mask pattern M may be formed on the active line 240. The mask pattern M may be configured to define the device isolation pattern. For example, the mask pattern M may include a hard mask layer, but the embodiments are not limited thereto. In an embodiment, the mask pattern M may be formed on the active line 240 to be partially overlapped with the bit line 210. For example, the mask pattern M may have a width Mw wider than a width Wd of the bit line 210. The width Mw of the mask pattern M may determine the first length La of the active pillar 245. That is, the width Mw of the mask pattern M may be substantially the same as the first length L1 of the upper region in the active pillars 245.

Referring to FIG. 13B, the active line 240 exposed through the mask pattern M may be etched until the lower insulation layer 205 is exposed to form a trench T1 and the active pillar 245. Because a pitch between the active pillars 245 may meet a standard of a high integrated semiconductor circuit device, the first length La of the active pillar 245 and a second length Lb of the trench T1 may be remarkably less than a height of the trench T1, for example, a height Ha of the word line structure. Thus, the trench T1 may also have a high aspect ratio.

Therefore, in the etching process for forming the trench T1, an amount of the etching gas may be gradually decreased toward the base layer 200. Thus, an etched amount of the lower region in the active line 240 may be less than an etched amount of the upper region in the active line 240. As a result, the second length Lb and Lb1 of the trench T1 may be gradually decreased toward the lower region. A width of the trench T1 may be substantially the same as the first width Wa and Wa1 of the active line 240. That is, because the active line 240 may be fixed by the pair of word line structures WLS at both sides of the active line 240, although the trench T1 may be formed in the active line 240, the widths of the active line 240 and the trench T1 may be maintained within the first width Wa and Wa1.

When the second length La1 of the lower region in the trench T1 is gradually decreased by the etching process for forming the trench T1 having the high aspect ratio, the first length La1 of the lower region in the active pillar 245 may be increased. For example, the first length La1 of the lower region in the active pillar 245 may be represented by following Formula 1.

$$La 1 = La + ( Lb - Lb 1 ) \qquad Formula 1$$

As a result, the first width Wa and Wa1 of the active pillar 245 may be gradually decreased toward the lower region. In contrast, the first length La and La1 of the active pillar 245 may be gradually increased toward the lower region.

Therefore, the active pillar 245 may have the width gradually decreased toward the lower region and the length gradually increased toward the lower region so that the contact area between the active pillar 245 and the bit line 210 and the total volume may be maintained.

Referring to FIG. 13C, an insulation layer 248 may be formed on the base layer 20 to fill up the trench T1 with the insulation layer 248. The insulation layer 248 may have good gap-filling characteristics. The insulation layer 248 may be planarized until the upper surface of the active pillar 245 is exposed to form the device isolation pattern 250 in the trench T1 as shown in FIG. 11D. As mentioned above, the shape of the device isolation pattern 250 may be substantially the same as the shape of the trench T1. Thus, the device isolation pattern 250 may have the second width Wb and Wb1 and the second length Lb and Lb1. The second width Wb and Wb1 of the device isolation pattern 250 may be substantially the same as the first width Wa and Wa1. The second length Lb and Lb1 of the device isolation pattern 250 may be different from the first length La and La1.

Referring to FIGS. 12A to 12D, a source S may be formed in the upper region of the active pillar 245. A drain D may be formed in the lower region of the active pillar 245. A capacitor electrode 260 may be formed on the active pillar 245. The capacitor electrode 260 may have contact with the source S.

In an embodiment, conductive impurities, for example, n type impurities may be implanted into the upper region and the lower region of the active pillar 245. The conductive impurities may be implanted into desired positions by a control of ion implantation energy, for example, a control of an implantation depth. The n type impurities may be activated by an annealing process to form the source S and the drain D in the upper region and the lower region of the active pillar 245, respectively. In order to partially overlap the drain D with the first work function layer 220a, the ion implantation energy and diffusion lengths of the impurities may be controlled. In order to partially cover the source S with the third work function layer 220c, the ion implantation energy and the diffusion length of the impurities may also be controlled.

Alternatively, the thicknesses of the first to third work function layers 220a, 220b and 220c may be determined in accordance with the diffusion lengths of the impurities in the drain D and the source S.

According to embodiments of the present disclosure, although the width Wa1 of the lower region with respect to the width Wa of the upper region in the active pillar 245 may be decreased by the high aspect ratio, the length La1 of the lower region with respect to the length La of the upper region in the active pillar 245 may be increased. Thus, the volume of the lower region in the active pillar 245 may be compensated to reduce the variations of the volume of the active pillar 245 and the contact area between the drain D and the bit line, thereby readily controlling a distribution of the electrical characteristic of the vertical transistor. An ohmic contact layer OC may be interposed between the source S and the capacitor electrode 260. The ohmic layer OC may include a metal silicide layer, but the embodiments are not limited thereto. Although not depicted in drawings, a dielectric layer and a plate electrode may be sequentially formed on the capacitor electrode 260 to form the data storage.

The active pillar 245 may be formed by the self-organization by forming the device isolation pattern 250 in the active line 240 having the high aspect ratio. The width of the active pillar 245 may be defined by the active line 240 to have the first width Wa and Wa1 gradually decreased toward the lower region. The active pillar 245 may be emerged from the device isolation pattern 250 having the second length Lb and Lb1 gradually decreased toward the lower region so that the active pillar 245 may have the first length La and La1 gradually increased toward the lower region.

Therefore, the area of the bottom surface of the active pillar 245, i.e., the contact area between the active pillar 245 and the bit line 210 may be secured and the volume of the active pillar 245 may be compensated to prevent the lower channel region of the vertical transistor from being decreased.

That is, the variation of the volume of the active pillars 245 may be reduced so that the overlap area between the active pillars 245 and the word line structure WLS, i.e., the vertical gate may be uniform to secure the uniform electrical characteristics of the vertical transistors. Further, an off-current in the lower region of the active pillar 245 in an off operation may be prevented by compensating the volume of the lower region of the active pillar 245.

Furthermore, the first to third work function layers 220a, 220b and 220c may have a thicknesses in accordance with the diffusion lengths of the impurities by the deposition process for readily controlling the thicknesses. The drain D may be formed in the active pillar 245 by the ion implantation process having the good depth control. The source S may be formed in the active pillar 245. The drain D may correspond to the first work function layer 220a. The source S may correspond to the third work function layer 220c. Thus, a junction distribution of the 3D transistor may be readily controlled. Further, the area of the active pillar and the volume compensation used for the target fine pattern may be performed without the additional mask and the additional etching process so that the cost and the time for the semiconductor integrated circuit device may be reduced. In embodiments of the present disclosure, the active pillar may include the target fine pattern, but the embodiments are not limited thereto. For example, the target fine pattern may include vertical patterns such as vertical plugs having the high aspect ratio.

The above described embodiments of the present disclosure are intended to illustrate and not to limit the embodiments. Various alternatives and equivalents are possible. The invention is not limited by the embodiments described herein. Nor is the invention limited to any specific type of semiconductor device. Other additions, subtractions, or modifications which are apparent in view of the present disclosure are intended to fall within the scope of the appended claims. Furthermore, the embodiments may be combined to form additional embodiments.

1. A semiconductor integrated circuit device comprising:
a target fine pattern having a first width gradually decreased toward a lower region of the target fine pattern, a first length gradually increased toward the lower region of the target fine pattern, and a first height greater than a maximum value of the first length and a maximum value of the first width; and
an adjacent fine pattern having contact with the target fine pattern along a lengthwise direction, the adjacent fine pattern having a second width gradually decreased toward a lower region of the adjacent fine pattern, a second length gradually decreased toward the lower region of the adjacent fine pattern, and the first height.

2. The semiconductor integrated circuit device of claim 1, wherein a difference between the first length of the lower region of the target fine pattern and the first length of an upper region of the target fine pattern is substantially identical to a difference between the second length of the upper region of the adjacent fine pattern and the second length of the lower region of the adjacent fine pattern.

3. The semiconductor integrated circuit device of claim 1, wherein the first width is substantially identical to the second width.

4. The semiconductor integrated circuit device of claim 1, wherein the target fine pattern comprises at least one of a semiconductor pattern and a conductive pattern.

5. The semiconductor integrated circuit device of claim 1, wherein the adjacent fine pattern comprises an insulation pattern.

6-8. (canceled)

9. A semiconductor integrated circuit device comprising:
a pair of word line structures having a first height, and extending parallelly in a first direction divided by a recess; and
at least one active pillar and at least one device isolation pattern alternately arranged in the recess between the pair of word line structures,
wherein the at least one active pillar has a first width gradually decreased toward a lower region of the at least one active pillar, a first length gradually increased toward the lower region of the at least one active pillar, and the first height, and
wherein the at least one device isolation pattern has a second width gradually decreased toward the lower region of the at least one device isolation pattern, a second length gradually decreased toward the lower region of the at least one device isolation pattern, and the first height.

10. The semiconductor integrated circuit device of claim 9, wherein the first width and the second width are parallel to a second direction substantially perpendicular to the first direction, and the first width is substantially identical to the second width.

11. The semiconductor integrated circuit device of claim 9, wherein a direction corresponding to the first length and the second length are parallel to the first direction.

12. The semiconductor integrated circuit device of claim 9, further comprising a gate dielectric layer interposed between the at least one active pillar and the pair of word line structures.

13. The semiconductor integrated circuit device of claim 9, further comprising a base layer including a plurality of bit lines and a lower insulation layer, the plurality of bit lines extending in a second direction substantially perpendicular to the first direction, and the lower insulation layer configured to electrically isolate the plurality of bit lines from each other.

14. The semiconductor integrated circuit device of claim 13, wherein a part of the plurality of bit lines is exposed through the recess and the at least one active pillar is formed on the exposed part of the plurality of bit lines through the recess.

15. The semiconductor integrated circuit device of claim 14, further comprising:
a drain formed in a lower region of the at least one active pillar adjacent to each bit line; and
a source formed in an upper region of the at least one active pillar.

16. The semiconductor integrated circuit device of claim 15, further comprising a capacitor electrode formed on the source.

17. The semiconductor integrated circuit device of claim 16, wherein an ohmic contact layer is formed between each bit line and the drain and/or the capacitor electrode and the source.

18. The semiconductor integrated circuit device of claim 15, wherein each pair of the word line structures comprises:
a first insulating interlayer formed on the base layer;
a word line conductive layer formed on the first insulating interlayer; and
a second insulating interlayer formed on the word line conductive layer.

19. The semiconductor integrated circuit device of claim 18, wherein the word line conductive layer comprises:
a first work function layer formed on the first insulating interlayer and positioned adjacent to the drain;
a second work function layer formed on the first work function layer; and
a third work function layer formed on the second work function layer,
wherein the second work function layer has a work function higher than a work function of at least one of the first and third work function layers.

20-25. (canceled)
